(19) United States
(12) Patent Application Publication
(10) Pub. No.: US 2006/0022558 A1
(43) Pub. Date: Feb. 2, 2006

(54) External electrode on a piezoceramic multi-layer actuator

(76) Inventors: Reiner Bindig, Bindlach (DE); Hans-Jurgen Schreiner, Neunkirchem am Sand-Rollhofen (DE); Jurgen Schmieder, Lauf (DE)

Correspondence Address: FULBRIGHT & JAWORSKI, LLP, 666 FIFTH AVE, NEW YORK, NY, 10103-3198, US

(21) Appl. No.: 10/520,357

(22) PCT Filed: Jul. 18, 2003
(86) PCT No.: PCT/EP03/07893

§ 371 Date: Jun. 17, 2005

(30) Foreign Application Priority Data
Jul. 19, 2002 (DE) 102 33 057.3
Jun. 20, 2003 (DE) 103 27 902.4

(51) Int. Cl. H01L 41/047

(52) U.S. Cl. 310/366

(57) ABSTRACT

In external electrodes on piezoceramic multi-layer actuators, high tensile stresses act during operation on the insulating region below the base metallic coating. Problems are caused by the linking of the electrode with a conductive connection, via which the electric voltage is to be supplied. The soldering or welding process reinforces the external electrode, which thus loses elasticity at the soldering or welding point. During operation, mechanical shear stresses then occur beneath said soldering or welding points, as the electrode region lying above no longer expands. After several million operating cycles, this causes the external electrode together with the base metallic coating to become detached, thus leading to the failure of the component. The invention is characterised in that the external electrode (23, 24; 26, 27) consists of alternating layers of conductive materials (19) and non-conductive materials (22, 25), located one on top of the other, that one of the two outer layers of conductive materials (19) is connected to the base metallic coating (11) of the actuator (1) and the other is connected to the supply conductor (6) for the voltage, and that the layers of conductive materials (19) are interconnected in a conductive manner.

The invention relates to an external electrode for a piezoceramic actuator.

Multilayer piezoceramic actuators are produced as monoliths, that is to say the active material, on which the internal electrodes are applied by a screen printing method before sintering, is assembled as a so-called green film into a stack which is pressed to form a green body. The green body is generally pressed by lamination under the effect of temperature and pressure in laminating moulds.

FIG. 1 schematically represents a greatly enlarged view of a multilayer piezoceramic actuator 1 produced in such a way. The actuator consists of stacked thin layers 2 of piezoelectrically active material, for example lead zirconate titanate (PZT), with conductive internal electrodes 3 being arranged between them and alternately routed to the actuator surface. External electrodes 4, 5 connect the internal electrodes 3. The internal electrodes 3 are therefore electrically connected in parallel and formed into two groups. The two external electrodes 4, 5 are the connecting poles of the actuator 1. They are connected to a voltage source (not shown here) via the terminals 6. If an electrical voltage is applied to the external electrodes 4, 5 via the terminals 6, this will be transferred in parallel to all the internal electrodes 3 and induce an electric field in all the layers 2 of the active material, which therefore mechanically deforms. The sum of all these mechanical deformations is available at the end face of the head region 7 and at the end face of the foot region 8 of the multilayer actuator 1 as a useful extension and/or force 9.

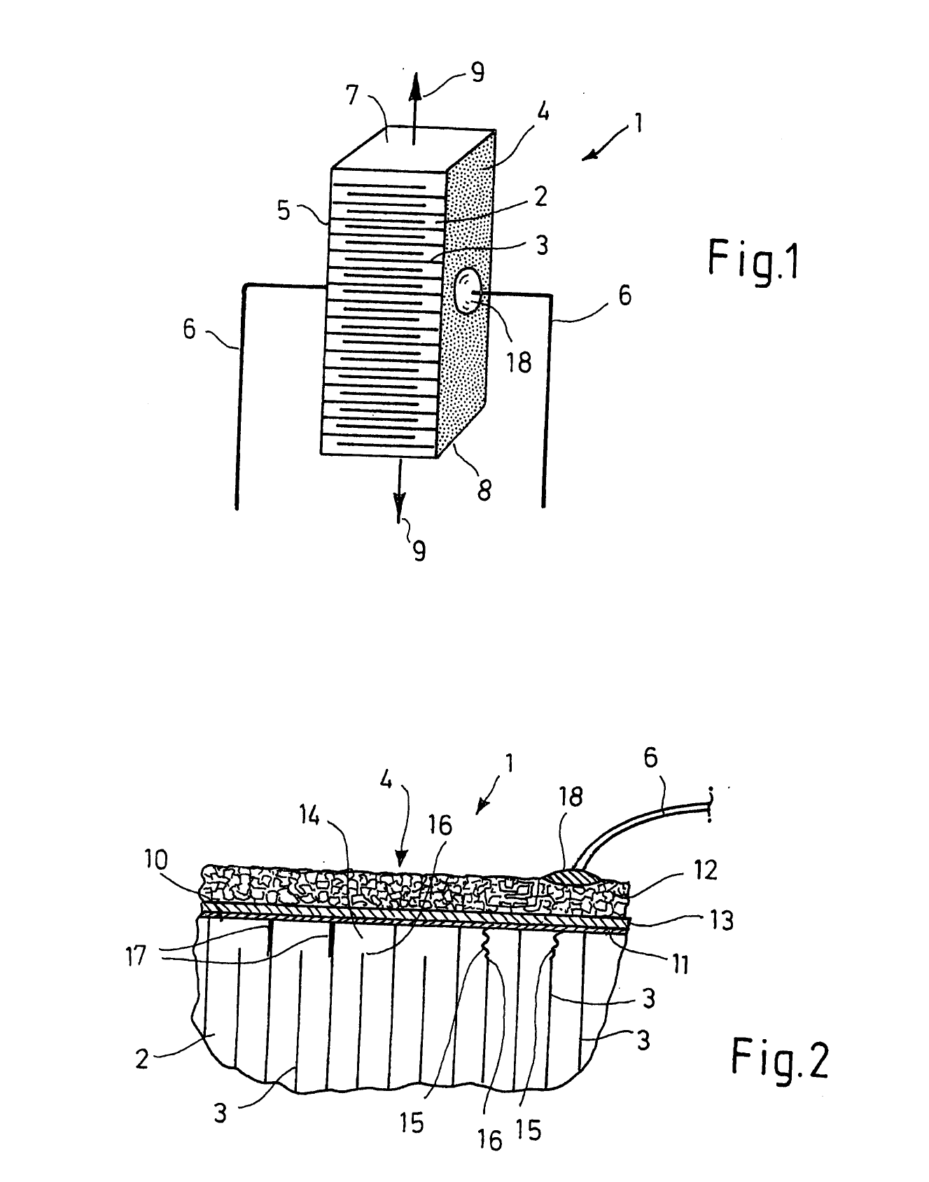

FIG. 2 shows a section through an external electrode 4 and the surface of a multilayer piezoceramic actuator 1 according to the prior art. On the thin layers 2 of the piezoelectrically active material, which are pressed to form a stack, in the vicinity of internal electrodes 3 fed out at the surface 10 of the multilayer actuator 1, a base metallization 11 is applied in order to connect internal electrodes 3 of the same polarity, for example by electrolytic methods or screen printing of metal paste. This base metallization 11 is reinforced with a further layer of a metallic material, for example by a structured metal sheet or a wire mesh as a three-dimensionally structured electrode 12, as is disclosed by EP 0 844 678 A1. The connection of the three-dimensionally structured electrode 12 to the base metallization 11 is established by means of a connecting layer 13, generally a layer of solder. At least one soldering bead of the electrical terminal wire 6 is soldered to the three-dimensionally structured electrode 12 at the contact position 18.

In the case of external electrodes on the surface 10 of an actuator 1 which are constructed as described above, strong tensile stresses during operation act on the inactive region, that is to say the insulating region 14 which lies below the base metallization 11. Since this insulating region 14 forms a homogeneous unit together with the base metallization 11 and the connecting layer 13, the said unit fails and cracks are formed when the tensile strength of the weakest component is exceeded. The cracking process in question occurs after about 10⁶ working cycles. Owing to the stresses which are encountered, the cracks 15 generally propagate from the brittle base metallization 11 of low tensile strength into the insulating region 14, where they are absorbed by regions with high tensile stresses, preferably at the electrode tips 16 of the electrodes 3 not touching the base metallization 11, or they begin in the regions of maximum tensile stress at the electrode tips 16 and propagate in the direction of the base metallization 11. The spreading of a crack 17 along an internal electrode 3 which touches the base metallization 11 is categorised as uncritical since such a cracking process does not impair the function of the actuator. If the base metallization 11 is split by a crack, then the resilient three-dimensionally structured electrode 12 acts as an electrical bridge so that the crack does not affect the properties or the life of the actuator 13. Cracks 15 which propagate uncontrolled through the insulating region 14, however, are highly critical since they reduce the insulation distance and greatly increase the likelihood of an actuator failure due to arcing.

Moreover, the electrodes constructed in such a way lead to problems when attaching a conductive connection through which an electrical voltage is intended to be delivered.

According to the prior art, a wire 6 is soldered or welded to a three-dimensionally structured electrode 12 at the contact point 18 as represented in FIG. 2. The soldering or welding stiffens the three-dimensionally structured electrode 12, however, so that it loses elasticity at the solder or weld point 18. Mechanical shear stresses then occur below these solder or weld points 18 during operation, since the electrode region lying above no longer expands along with the movement. After a few million operating cycles, this can lead to detachment of the metal electrode together with the base metallization and therefore failure of the component.

It is known from DE 100 26 005 A1 that the three-dimensionally structured electrode may protrude beyond the actuator and the electrical contact can be soldered there, optionally on the folded or rolled electrode. The protruding ends are insulated by shrink-fit tubing. This type of terminal is elaborate and leads to a complicatedly constructed external electrode. Notch effects can occur at the bending points of the electrode.

It is known from DE 199 09 452 C1 to provide a piezoelectrically inactive region on one side of the actuator, for example at the foot, and to apply the electrical contact in this region. The passive foot leads to a significantly reduced stiffness and expansion for an equivalent overall length of the component, because the passive foot acts like a stiff spring and shortens the active region.

It is an object of the present invention to improve the attachment of the voltage supply lead to the external electrodes by means of the configuration of the electrodes.

The object is achieved in that the external electrode consists of conductive material layers and nonconductive material layers arranged alternately above one another, in that one of the two outlying conductive material layers is connected to the base metallization of the actuator and the other is connected to the voltage supply lead, and in that the conductive material layers are electrically connected to one another.

Since the conductive material layers and nonconductive material layers are arranged alternately above one another, the conductive material layers are mechanically decoupled from each other. The electrical interconnection is established separately, or is obtained by folding a continuous foil as the conductive material. The lower conductive layer, which is connected to the base metallization by soldering or adhesive bonding, can therefore move independently of the upper layers within certain limits and thus compensate for stresses which occur.

A soldered or welded electrical contact is connected only to the top conductive layer. This avoids soldering through the layer.

Therefore, the contact of the terminal wire with the outer conductive layer of the external electrode no longer stiffens the electrode. The forces acting on the external electrode via the base metallization are advantageously attenuated owing to the layered structure, so that they have no effect at the connection position.

On actuators which have external electrodes according to the invention, electrical contacts may be applied at any place on the external electrode without this having any effect on the life or other properties of the actuator. It is therefore possible to produce compact actuator modules without elaborate or disruptive protection measures, such as those which are known from the prior art.

An external electrode constructed according to the invention consists of at least two layers of a conductive material and a layer of a nonconductive material arranged between them.

The conductive material may consist of metal foils, which are easy to process owing to their small thickness. The thickness of the foils is approximately between 30 μm and 200 μm, preferably between 50 μm and 100 μm. The foils may also be structured, for example by stamping. Their overall thickness can thereby be increased to three times the foil thickness.

The conductive material layers may also be three-dimensionally structured. They will not then be solid layers, but instead will consist of metal gauze or fabric, of a mesh or of metal foam.

The gauzes, fabrics or meshes of metal wires have a thickness of about 100 μm to 200 μm. The lattice width of the fabrics or meshes is between about 100 μm and 200 μm, with wire diameters of between about 50 μm and 100 μm.

The nonconductive material layers consist of a resilient plastic, preferably a thermoplastic such as polytetrafluoroethylene (Teflon) or polyimide. The layers are films with a thickness of about 10 μm to about 100 μm.

The conductive material of a layer may also be coated with the nonconductive material of a layer. They may, for example, be foils coated with plastic on one side. These, for example, can be folded to form an external electrode according to the invention. Conductive material layers and nonconductive material layers may furthermore be laminated together alternately.

The individual conductive material layers may consist of different metallic materials. For example, the conductive material, at least of the layer which is soldered or adhesively bonded to the actuator material, may be selected so that it has a coefficient of thermal expansion matched to the ceramic material of the actuator.

In order to establish the electrical connection between the metallic material layers, contacts are made via or around these layers. For this purpose, the layers are electrically connected to one another on each of their long sides, for example by soldering their protruding sides.

It is also possible for a conductive material, preferably in the form of a foil or a gauze, to be folded into a meandering or spiral shape so that the nonconductive material respectively lies as a layer between the folds, or inside a turn. The following effect is achieved by this: interrupting the layers of the foil or the gauze with plastic layers ensures that a soldered or welded electrical contact is only connected to the upper conductive layer. This avoids soldering through and stiffening the layers.

The production of an actuator according to the invention will be described below. A low-sintering piezoceramic according to DE 198 40 488 is prepared with an organic binder system as a 125 μm thick film. An internal electrode paste of silver-palladium powder in a weight ratio of 70/30 and a suitable binder system is applied to this film by means of screen printing. A multiplicity of such films are stacked and pressed to form a laminate. The laminate is divided into individual rod-shaped actuators, which are pyrolyzed at about 400° C. and sintered at about 1100° C. The actuator preforms are then mechanically processed on all sides.

The base metallization, for example consisting of a suitable silver-palladium termination paste, is applied by means of a screen printing/burn-in process.

A structured and folded external electrode according to the invention is soldered onto this base metallization.

The electrical connection may then be applied, for example by soldering or welding. This working step may also be delayed, for example if a contact pin is applied to the folded electrode before soldering onto the actuator. The actuators are subsequently protected by a layer of varnish. It is also possible for the contact not to be established until after the varnishing, in which case the soldering or welding region generally needs to be kept free of varnish. The actuators are subsequently polarised and electrically measured.

The present invention will be explained in more detail with reference to exemplary embodiments.

FIG. 1 schematically shows the structure of a monolithic multilayer actuator according to the prior art,

FIG. 2 shows a detail of the actuator according to FIG. 1 with the typical cracks which are encountered after about 10⁶ working cycles,

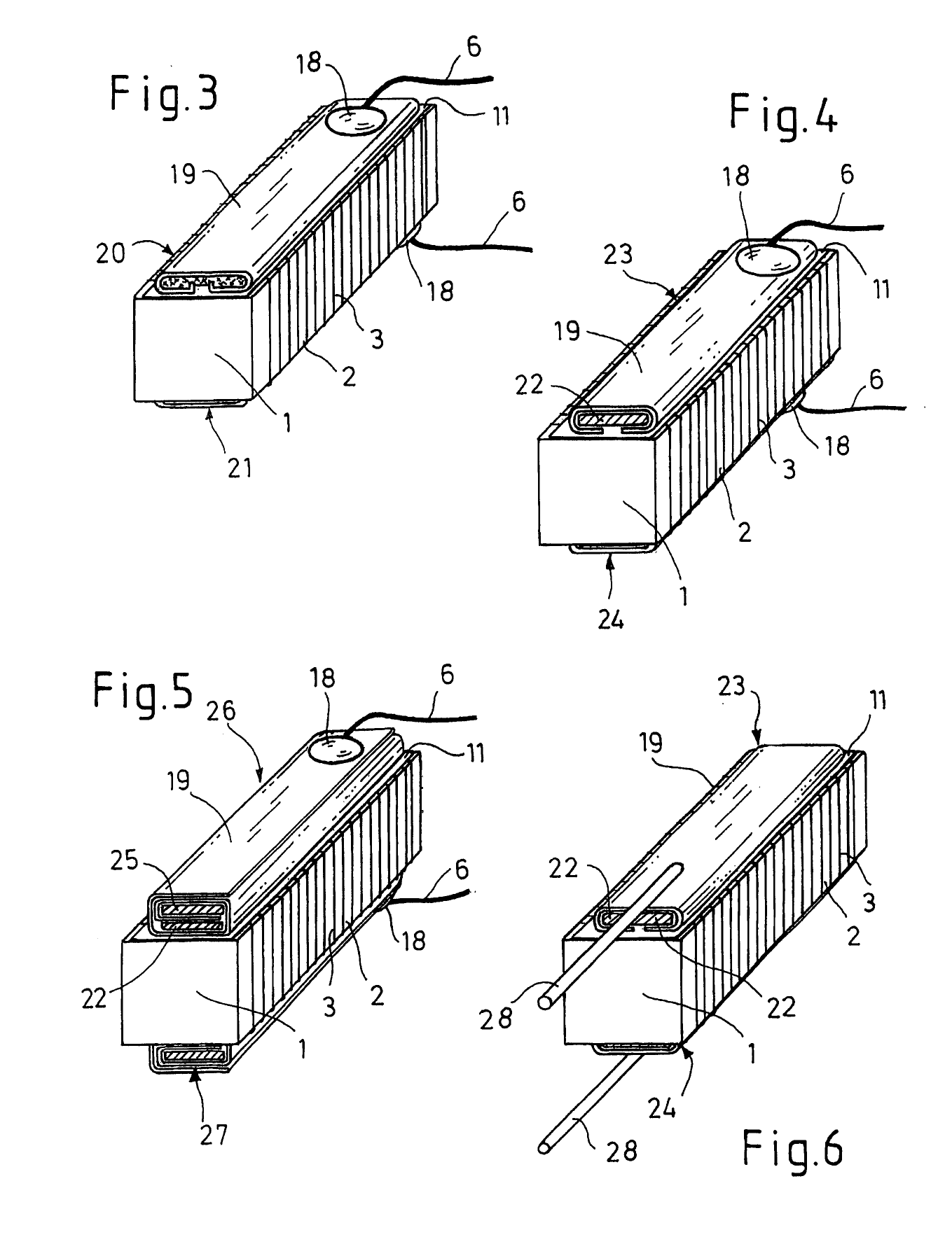

FIG. 3 shows an actuator having a folded metal mesh electrode according to the prior art,

FIG. 4 shows an actuator a having a singly folded metal mesh electrode according to the invention and a plastic inlay,

FIG. 5 shows an actuator having a spirally folded metal mesh electrode according to the invention and two plastic inlays, and

FIG. 6 shows an actuator having a singly folded metal mesh electrode according to the invention and a plastic inlay, and terminal pins welded on.

The production of the external electrodes according to the invention will be explained with reference to four exemplary embodiments.

As indicated above, actuator preforms 1 are prepared with dimensions of 10 mm×10 mm (base area) and a length of 30 mm. The thickness of a single ceramic layer 2 is 100 μm after the sintering, and the thickness of an internal metallization layer is 2 μm. The base metallization 3 is produced by screen printing using a commercially available termination paste, and burnt in for 30 minutes at 750° C. in air. The layer thickness after burning in is from 10 μm to 12 μm. These actuator preforms are then processed in the following way:

### EXAMPLE 1

According to FIG. 3, a wire gauze 19 of copper-tin alloy (CuSn₆) wires with wire diameters of 0.1 mm and a lattice width of 0.2 mm is electrolytically coated to a thickness of 20 μm with solder (SnPb₁₀) to form the conductive material. An 8 mm wide and 29 mm long strip is cut from the gauze at an angle of 45° to the direction of the warp wires. This strip is folded lengthwise so that the two edges lie in the middle.

External electrodes 20, 21 of this type are soldered at the opposite terminal surfaces onto the base metallization 11 of the actuator preform, for example by a reflow soldering method. A solder point 18 for the terminal wires 6 is respectively applied to the opposite external electrodes 20, 21 in the vicinity of one actuator end face. This procedure represents the prior art. The soldering time is 10 minutes at 240° C.

### EXAMPLE 2

According to FIG. 4, a wire gauze 19 of copper-tin alloy (CuSn₆) wires with wire diameters of 0.1 mm and a lattice width of 0.2 mm is electrolytically coated to a thickness of 20 μm with solder (SnPb₁₀). An 8 mm wide and 29 mm long strip is cut from the gauze at an angle of 45° to the direction of the warp wires. A strip 22 of PTFE polymer with the dimensions 3.5 mm×29 mm is placed centrally on this strip. The gauze strip 19 is folded lengthwise around it, so that the two edges lie in the middle.

External electrodes of this type are soldered onto the base metallization of the actuator preform, for example by a reflow soldering method. A solder point 18 for the terminal wires 6 is respectively applied to the opposite external electrodes 23, 24 in the vicinity of an actuator end face. The soldering time is 10 minutes at 240° C.

### EXAMPLE 3

According to FIG. 5, a wire gauze 19 of copper-tin alloy (CuSn₆) wires with wire diameters of 0.1 mm and a lattice width of 0.2 mm is electrolytically coated to a thickness of 20 μm with solder (SnPb₁₀). A 16 mm wide and 29 mm long strip is cut from the gauze at an angle of 45° to the direction of the warp wires. A strip 22 of PTFE polymer with the dimensions 3.5 mm×29 mm is placed off-centre on this strip. The gauze strip 19 is folded lengthwise around it. Another PTFE strip 25 is put it, and the gauze strip is folded around spirally.

External electrodes of this type are soldered onto the base metallization 11 of the actuator preform, for example by a reflow soldering method, so that the doubled-up metal mesh layer faces away from the actuator. A solder point 18 for the terminal wires 6 is respectively applied to the opposite external electrodes 26, 27 in the vicinity of an actuator end face. The soldering time is 10 minutes at 240° C.

### EXAMPLE 4

According to FIG. 6, which corresponds to Exemplary Embodiment 2 according to FIG. 4, a wire gauze 19 of an iron-nickel alloy (FeNi₄₂) with wire diameters of 0.08 mm and a lattice width of 0.18 mm is electrolytically coated to a thickness of 6 μm with copper and to a thickness of 20 μm with solder (SnPb₁₀). An 8 mm wide and 29 mm long strip is cut from the gauze at an angle of 45° to the direction of the warp wires. A strip 22 of polyimide polymer with the dimensions 3.5 mm×29 mm is placed centrally on this strip. The gauze strip is folded lengthwise around it so that the two edges lie in the middle. A metal pin 28 with a diameter of 0.8 mm is welded onto the external electrode 23, 24 produced in this way, by means of resistance welding, overlapping by about 5 mm so that the pin 28 protrudes beyond the wire mesh 19 on one side.

The matched coefficient of thermal expansion of the mesh material and the already preformed terminal pin are advantageous in this embodiment,

External electrodes of this aforementioned type are soldered onto the base metallization of the actuator preform, for example by a reflow soldering method. The soldering time is 10 minutes at 240° C.

The four variants are coated with silicone varnish by a suitable method, for example by immersion or spraying.

After the varnish has been dried and set, the varnish is removed from the solder points of variants 1 to 3 and a terminal wire is soldered on.

The actuators are prestressed with 2000 N in test frames and driven with a trapezoidal signal. The drive voltage is increased from 0 V to 200 V in 100 μs, kept at 200 V for 1 μs and then reduced to 0 V in 100 μs. The repetition frequency is 200 Hz. The actuators reach operating temperatures of from 150° C. to 160° C. during this.

Example 1 already shows significant detachment of the mesh electrode from the ceramic in the vicinity of the solder points at 10⁷ cycles. After 2·10⁷ cycles, the actuator is destroyed by arcing at the solder points.

Examples 2 to 4 show mutually identical behaviours, which differ significantly from Example 1. Even at 10⁹ cycles, no mesh detachment or arcing occurs in any of the examples.

The person skilled in the art may select various methods when producing the external electrodes according to the invention. For example, the external electrodes may be folded from thin sheet metal coated with plastic or, as described, they may be folded as metal mesh around a plastic strip. Production similar to a printed circuit board is also possible, by laminating the plastic and metal layers onto one another and making electrical contact via them. For example, this printed circuit board may also enclose and protect the entire actuator as preformed flexboard. Instead of soldering the external electrodes onto the actuator, it is also possible to use conductive adhesives. The materials to be used depend essentially on the intended working conditions. PTFE and polyimide materials, and expansion alloys such as FeNi₄₂, are suitable in particular for high temperatures and a rapid temperature change.

1. External electrode for a multilayer piezoceramic actuator, characterised in that the external electrode (23, 24; 26; 27) consists of conductive material layers (19) and nonconductive material layers (22, 25) arranged alternately above one another, in that one of the two outlying conductive material layers (19) is connected to the base metallization (11) of the actuator (1) and the other is connected to the voltage supply lead (6), and in that the conductive material layers (19) are electrically connected to one another.

2. External electrode according to claim 1, characterised in that it consists of at least two layers of a conductive material (19) and a layer of a nonconductive material (22, 25) arranged between them.

3. External electrode according to claim 1 or 2, characterised in that each conductive material layer (19) consists of a metal foil.

4. External electrode according to claim 3, characterised in that the foil (19) has a thickness of about 30 μm to about 200 μm, preferably between 50 μm and 100 μm.

5. External electrode according to claim 3 or 4, characterised in that the foil (19) has a spatial structure, and in that the layer can therefore attain up to three times the thickness of the foil.

6. External electrode according to claim 1 or 2, characterised in that the conductive material layers (19) are three-dimensionally structured.

7. External electrode according to claim 6, characterised in that the conductive material layers (19) consist of metal gauze or fabric, of a mesh or of metal foam.

8. External electrode according to claim 7, characterised in that the gauzes, fabrics or meshes of the conductive material layers (19) have a thickness of about 100 μm to 200 μm.

9. External electrode according to claim 7 or 8, characterised in that the lattice widths of the fabrics or meshes of the conductive material layers (19) are between about 100 μm and 200 μm, and the wire diameter is between about 50 μm and 100 μm.

10. External electrode according to one of claims 1 to 9, characterised in that the nonconductive material (22, 25) is a resilient plastic, preferably a thermoplastic such as polytetrafluoroethylene (PTFE) or polyimide.

11. External electrode according to claim 10, characterised in that the nonconductive material (22, 25) is a plastic, in the form of films with a thickness of about 10 μm to about 100 μm.

12. External electrode according to one of claims 1 to 11, characterised in that the conductive material (19) is coated with the nonconductive material (22, 25).

13. External electrode according to one of claims 1 to 12, characterised in that the individual conductive material layers (19) consist of different metallic materials.

14. External electrode according to one of claims 1 to 13, characterised in that the conductive material (19), at least of the layer which is soldered to the actuator material, has a coefficient of thermal expansion matched to the ceramic material of the actuator (1).

15. External electrode according to one of claims 1 to 14, characterised in that it is produced by colaminating the conductive material layers (19) and the nonconductive material layers (22, 25).

16. External electrode according to one of claims 1 to 15, characterised in that the electrical connection between the conductive material layers (19) is established by via-contacts or contacts leading around.

17. External electrode according to claim 16, characterised in that the conductive material layers (19) are respectively connected to one another on their long sides.

18. External electrode according to one of claims 1 to 14, characterised in that the conductive material (19) is folded into a meandering or spiral shape, and in that the nonconductive material (22, 25) is respectively arranged between two superimposed layers of the conductive material (19).

19. External electrode according to one of claims 1 to 14, characterised in that the conductive material (19) is bent into a C-shape, in that it encloses the nonconductive material layer (22), and in that the bent sides are connected to the base metallization (11) of the actuator (1).

20. External electrode according to one of claims 1 to 19, characterised in that the conductive material (19) consists of a copper or silver alloy.

21. External electrode according to one of claims 1 to 19, characterised in that the conductive material (19) consists of an iron-nickel alloy or an iron-nickel-cobalt alloy.

22. External electrode according to one of claims 1 to 21, characterised in that it is connected to the base metallization (11) of the actuator (1) by soldering or by bonding with a conductive adhesive.
